(19) United States
(12) Patent Application Publication
(10) Pub. No.: US 2024/0332378 A1
(43) Pub. Date: Oct. 3, 2024

(54) SEMICONDUCTOR DEVICE

(71) Applicant: Samsung Electronics Co., Ltd., Suwon-si (KR)

(72) Inventors: Younggwon KIM, Suwon-si (KR); Seung Geun JUNG, Suwon-si (KR); Myung Gil KANG, Suwon-si (KR); Gyeom KIM, Suwon-si (KR); Dongwon KIM, Suwon-si (KR)

(73) Assignee: Samsung Electronics Co., Ltd., Suwon-si (KR)

(21) Appl. No.: 18/463,488

(22) Filed: Sep. 8, 2023

(30) Foreign Application Priority Data
Mar. 31, 2023 (KR) 10-2023-0043020

(51) Int. Cl. H01L 29/417; H01L 21/768; H01L 23/522; H01L 29/08; H01L 29/40

(52) U.S. Cl. CPC H01L 29/41733; H01L 21/76805; H01L 23/5226; H01L 29/0847; H01L 29/401; H01L 23/53295; H01L 29/42392; H01L 29/66439; H01L 29/66742; H01L 29/775; H01L 29/78696

(57) ABSTRACT

A semiconductor device may include a substrate, a lower pattern on the substrate, a channel pattern on the lower pattern, a source/drain pattern on both sides of the channel pattern, a gate structure surrounding the channel pattern, a contact electrode electrically connected to the source/drain pattern, an etch stop layer between the gate structure and the contact electrode, and a contact interface layer on the source/drain pattern. The contact interface layer may include a first region between the source/drain pattern and the contact electrode and a second region between the source/drain pattern and the etch stop layer.

### CROSS-REFERENCE TO RELATED APPLICATION

This application claims priority to and the benefit of Korean Patent Application No. 10-2023-0043020 filed in the Korean Intellectual Property Office on Mar. 31, 2023, the entire contents of which is incorporated herein by reference.

### BACKGROUND

### Field

The present disclosure relates to a semiconductor device.

### Description of the Related Art

A semiconductor is a material belonging to an intermediate area between a conductor and an insulator, and refers to a material that conducts electricity under certain conditions. Various semiconductor devices may be manufactured using the semiconductor materials, and for example, memory devices and the like may be manufactured. Such semiconductor devices may be used in various electronic devices.

As the electronics industry develops to a high degree, demands on the characteristics of semiconductor devices are gradually increasing. For example, demands for high reliability, high speed, and/or multifunctionality of semiconductor devices are gradually increasing. In order to satisfy these characteristics, structures within semiconductor devices may become increasingly complex and integrated. As the size of the transistor decreases, parasitic capacitance increases and thus the operating speed of the semiconductor device decreases, and reliability of the semiconductor device may deteriorate.

### SUMMARY

The present disclosure relates to a semiconductor device with improved reliability and a method for manufacturing the same.

According to an example embodiment, a semiconductor device may include a substrate; a lower pattern on the substrate; a channel pattern on the lower pattern; a source/drain pattern on both sides of the channel pattern; a gate structure surrounding the channel pattern; a contact electrode electrically connected to the source/drain pattern; an etch stop layer between the gate structure and the contact electrode; and a contact interface layer on the source/drain pattern. The contact interface layer may include a first region and a second region. The first region may be between the source/drain pattern and the contact electrode. The second region may be between the source/drain pattern and the etch stop layer.

According to an example embodiment, a semiconductor device may include a lower pattern on the substrate, a channel pattern on the lower pattern, a source/drain pattern on both sides of the channel pattern, a gate structure surrounding the channel pattern, a contact electrode electrically connected to the source/drain pattern, and a contact interface layer between the source/drain pattern and the contact electrode. The contact interface layer may include a first region and a second region. The first region may surround at least a portion of the contact electrode. The second region may extend from the first region along an upper surface of the source/drain pattern.

According to an example embodiment, a semiconductor device may include a lower pattern on the substrate, a channel pattern on the lower pattern, a source/drain pattern on both sides of the channel pattern, a gate structure surrounding the channel pattern, a contact electrode electrically connected to the source/drain pattern, an interlayer insulation layer between the gate structure and the contact electrode, and a contact interface layer on the source/drain pattern. The contact interface layer may include a first region and a second region. The first region may be between the source/drain pattern and the contact electrode. The second region may be between the source/drain pattern and the interlayer insulation layer. The second region of the contact interface layer may overlap the interlayer insulation layer in a thickness direction of the substrate.

According to embodiments, since the contact interface layer of the semiconductor device may include first and second regions, contact resistance between the contact electrode and the source/drain pattern is reduced, thereby securing reliability of the semiconductor device.

### BRIEF DESCRIPTION OF THE DRAWINGS

FIG. 1 is a top plan view showing a semiconductor device according to an embodiment.

FIG. 2 is a cross-sectional view taken along line A-A′ of FIG. 1.

FIG. 3 is a cross-sectional view taken along line B-B′ of FIG. 1.

FIG. 4 is a cross-sectional view taken along line C-C′ of FIG. 1.

FIG. 5 illustrates an enlarged cross-sectional view of region “S” of FIG. 2.

FIG. 6 is an enlarged cross-sectional view of a semiconductor device according to some embodiments, corresponding to region S of FIG. 2.

FIG. 7 is an enlarged cross-sectional view of region “P” of FIG. 4.

FIG. 8 to FIG. 10 are enlarged cross-sectional views of a semiconductor device according to some embodiments, corresponding to region S of FIG. 2.

FIG. 11 and FIG. 12 are enlarged cross-sectional views of a semiconductor device according to some embodiments, corresponding to region P of FIG. 4.

FIG. 13 is a cross-sectional view of a semiconductor device according to some embodiments, corresponding to a cross-sectional view taken along line A-A′ of FIG. 1.

FIG. 14 and FIG. 15 are cross-sectional views of a semiconductor device according to some embodiments, corresponding to a cross-sectional view taken along line C-C′ of FIG. 1.

FIG. 16, FIG. 18, FIG. 20, FIG. 22, FIG. 24, FIG. 26, FIG. 28 are cross-sectional views showing intermediate stages of a method of manufacturing a semiconductor device according to an embodiment, corresponding to a cross-sectional view taken along line A-A′ of FIG. 1.

FIG. 17, FIG. 19, FIG. 21, FIG. 23, FIG. 25, FIG. 27, FIG. 29 are cross-sectional views showing intermediate stages of a method of manufacturing a semiconductor device according to an embodiment, corresponding to a cross-sectional view taken along line C-C′ of FIG. 1.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In the description of the presented embodiments, parts or portions that are irrelevant to the description may be omitted, and identical or similar constituent elements throughout the specification may be denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., may be exaggerated for clarity. In the drawings, for ease of description, the thicknesses of some layers and areas may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Drawings of a semiconductor device according to an embodiment illustrates, merely as examples, a transistor including nanowires or nanosheets, a multi-bridge channel field effect transistor (MBCFET™), and a fin-type transistor (FinFET) including a channel region of a fin-type pattern, but is not limited thereto. A semiconductor device according to some embodiments may also include a tunneling transistor (tunneling FET), a 3D stack field effect transistor (3DSFET), a complementary field effect transistor (CFET), and the like.

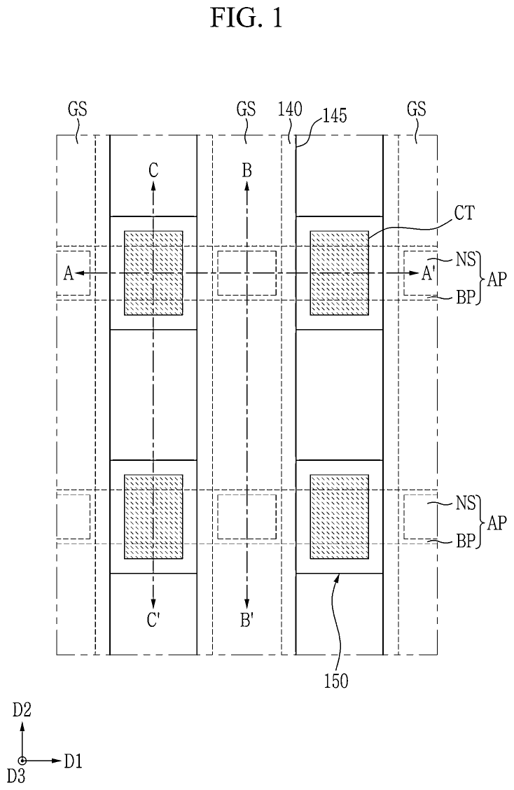

Hereinafter, a semiconductor device according to an embodiment is described with reference to FIG. 1 to FIG. 4.

FIG. 1 is a top plan view showing a semiconductor device according to an embodiment.

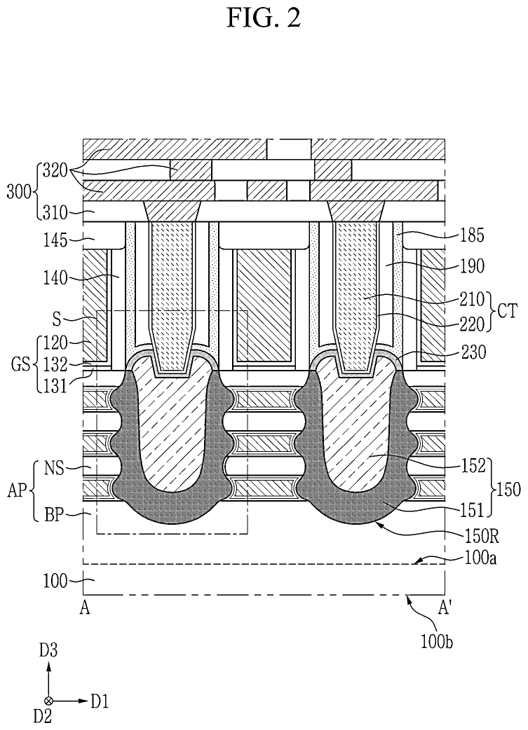

FIG. 2 is a cross-sectional view taken along line A-A′ of FIG. 1.

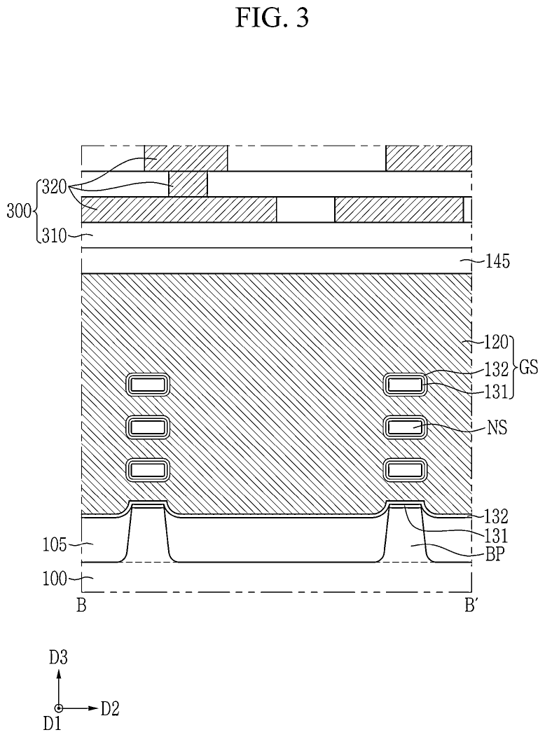

FIG. 3 is a cross-sectional view taken along B-B′ of FIG. 1.

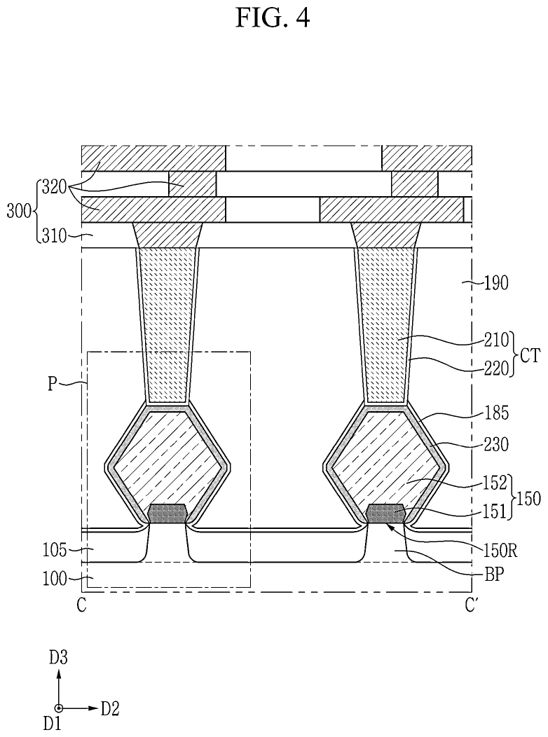

FIG. 4 is a cross-sectional view taken along line C-C′ of FIG. 1.

Referring to FIG. 1 to FIG. 4, a semiconductor device according to an embodiment includes a substrate 100, an active pattern AP, a gate structure GS, a source/drain pattern 150, an etch stop layer 185, an interlayer insulation layer 190, a contact electrode CT, and a contact interface layer 230.

The substrate 100 may be bulk silicon or silicon-on-insulator (SOI). Alternatively, the substrate 100 may be a silicon substrate, or other materials such as silicon germanium (SiGe), silicon germanium on insulator (SGOI), indium antimonide, lead tellurium compound, indium arsenic, indium phosphide, gallium arsenide or gallium antimonide, but is not limited thereto. The upper surface of the substrate 100 may be disposed as a plane parallel to the first direction D1 and the second direction D2 crossing the first direction D1.

The substrate 100 may include a first surface 100a and a second surface 100b facing each other. In the embodiments described later, the first surface 100a may be referred to as a front side of the substrate 100, and the second surface 100b may be referred to as a back side of the substrate 100.

The active pattern AP may be positioned on the substrate 100. The active pattern AP may extend in the first direction D1. For example, the active pattern AP may be positioned in a region where a PMOS is formed. For another example, the active pattern AP may be positioned in a region where an NMOS is formed.

The active pattern AP may be a multi-channel active pattern. The active pattern AP may include a lower pattern BP and a plurality of channel patterns NS. The lower pattern BP may protrude from the substrate 100. The lower pattern BP may extend in the first direction D1.

The plurality of channel patterns NS may be positioned on an upper surface of the lower pattern BP. The plurality of channel patterns NS may be spaced apart from the lower pattern BP in a third direction D3. Each channel pattern NS may be spaced apart in the third direction D3. Here, the third direction D3 may be a direction crossing the first direction D1 and the second direction D2. For example, the third direction D3 may be a thickness direction of the substrate 100. The second direction D2 may be a direction crossing the first direction D1.

FIG. 2 and FIG. 3 illustrate that three channel patterns NS are spaced apart from each other and stacked along the third direction D3, but this is only for convenience of description and example embodiments are not limited thereto. For example, four or more channel patterns NS may be spaced apart from each other along the third direction D3 and stacked.

FIG. 2 illustrates that a side surface of the channel pattern NS is curved, but example embodiments are not limited thereto. For example, the side surface of the channel pattern NS may be a combination of a curved surface and a flat surface, or may be entirely flat.

The lower pattern BP may be formed by etching a portion of the substrate 100 or may include an epitaxial layer grown from the substrate 100. The lower pattern BP may include silicon (Si) or germanium (Ge), which is an elemental semiconductor material. Also, the lower pattern BP may include a compound semiconductor, for example, a group IV-IV compound semiconductor or a group III-V compound semiconductor.

The group IV-IV compound semiconductor may be, for example, a binary compound or a ternary compound that include at least two of carbon (C), silicon (Si), germanium (Ge), tin (Sn).

The group III-V compound semiconductor may be for example, one of binary compound, ternary compound, or quaternary compound formed as a combination of at least one of aluminum (Al), gallium (Ga) and indium (In) as a group Ill element and one of phosphorus (P), arsenic (As) and antimony (Sb) as a group V element.

The channel pattern NS may include one of silicon (Si) or silicon germanium (SiGe), the group IV-IV compound semiconductor or the group III-V compound semiconductor, which are elemental semiconductor materials. Each channel pattern NS may include a same material as the lower pattern BP or a material different from that of the lower pattern BP.

In the semiconductor device according to an embodiment, the lower pattern BP may be a silicon lower pattern including silicon (Si), and the channel pattern NS may be a silicon sheet pattern including silicon (Si).

A field insulation layer 105 may be positioned on the substrate 100. The field insulation layer 105 may be positioned on a sidewall of the lower pattern BP. The field insulation layer 105 is not positioned on the upper surface of the lower pattern BP.

As an example, the field insulation layer 105 may entirely cover a side surface of the lower pattern BP. Unlike what is illustrated, the field insulation layer 105 may cover a portion of the sidewall of the lower pattern BP. In this case, a portion of the lower pattern BP may protrude beyond an upper surface of the field insulation layer 105 in the third direction D3.

Each channel pattern NS may be positioned higher than the upper surface of the field insulation layer 105. The field insulation layer 105 may include, for example, oxide, nitride, nitride oxide, or a combination thereof. Although it is illustrated that the field insulation layer 105 is a single layer, this is only for convenience of explanation, and example embodiments are not limited thereto.

The gate structure GS may be positioned on the substrate 100. The gate structure GS may extend in the second direction D2. The gate structure GS may be spaced apart from each other in the first direction D1.

The gate structure GS may be positioned on the active pattern AP. The gate structure GS may cross the active pattern AP on a plane. The gate structure GS may cross the lower pattern BP on a plane. The gate structure GS may surround respective the channel patterns NS.

Each of the gate structure GS may include a plurality of sub-gate structures and a main gate structure. The plurality of sub-gate structures may be positioned between the channel patterns NS adjacent to each other in the third direction D3 and between the lower pattern BP and the channel pattern NS. The main gate structure may be positioned on an uppermost the channel pattern NS.

The active pattern AP may include the plurality of channel patterns NS, and the gate structure GS may include the plurality of sub-gate structures. The number of sub-gate structures may be proportional to the number of channel patterns NS included in the active pattern AP. For example, the number of sub-gate structures may be the same as the number of channel patterns NS. For example, as shown in FIGS. 2 and 3, the number of sub-gate structures may be three. However, example embodiments are not limited thereto, and may include four or more sub-gate structures.

The plurality of sub-gate structures may be positioned between the upper surface of the lower pattern BP and a lower surface of a lowermost the channel pattern NS, and between an upper surface of the channel pattern NS and a lower surface of the channel pattern NS that face each other in the third direction D3. The plurality of sub-gate structures may be adjacent to the source/drain pattern 150 to be described later. The main gate structure may be positioned on the plurality of sub-gate structures and channel patterns NS. The main gate structure may be positioned on the upper surface of the channel pattern NS.

The gate structure GS may include a gate insulation layer 131, a gate dielectric layer 132, and a gate electrode 120 sequentially stacked from the channel pattern NS.

The gate electrode 120 may be positioned on the lower pattern BP. The gate electrode 120 may cross the lower pattern BP. The gate electrode 120 may surround the channel pattern NS.

At least a portion of the gate electrode 120 may be positioned on the stacking structure of the channel pattern NS. Another portion of the gate electrode 120 may be disposed to cover both side surfaces of the channel pattern NS in the stacked structure. In this case, four sides of the channel pattern NS may be surrounded by the gate electrode 120.

The gate electrode 120 may be positioned on one side of the source/drain pattern 150. The source/drain patterns 150 may be positioned on both sides of the gate electrode 120 in the first direction D1.

The gate electrode 120 may include at least one of a metal, a metal alloy, a conductive metal nitride, a metal silicide, a doped semiconductor material, a conductive metal oxide, and a conductive metal nitride oxide. The gate electrode 120 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but example embodiments are not limited thereto. The conductive metal oxide and the conductive metal nitroxide may include an oxidized form of the above material, but are not limited thereto.

The gate insulation layer 131 may extend along the upper surface of the lower pattern BP.

The gate insulation layer 131 may be in direct contact with the lower pattern BP, the source/drain pattern 150 and the channel pattern NS. The gate insulation layer 131 may be disposed between the channel pattern NS and the gate dielectric layer 132.

The gate insulation layer 131 may not extend along a side surface of a gate spacer 140 to be described later. The gate insulation layer 131 may include, for example, silicon oxide (SiO₂). However, example embodiments are not limited thereto, and the gate insulation layer 131 may extend along the side surface of the gate spacer 140.

The gate dielectric layer 132 may extend along the upper surface of the field insulation layer 105 and an upper surface of the gate insulation layer 131. The gate dielectric layer 132 may surround the plurality of channel patterns NS. The gate dielectric layer 132 may be positioned along a circumference of the channel pattern NS. The gate dielectric layer 132 may be disposed between the gate electrode 120 and the gate insulation layer 131. The gate dielectric layer 132 may be disposed between the gate electrode 120 and the channel pattern NS, and between the gate electrode 120 and the gate spacer 140.

The gate dielectric layer 132 may include, for example, a high-k material. The high-k material may be hafnium oxide (HfO), aluminum oxide (AlO) or tantalum oxide (TaO).

A semiconductor device according to an embodiment may further include the gate spacer 140 and a capping layer 145.

The gate spacer 140 may be positioned on a side surface of the gate structure GS. For example, the gate spacer 140 may be positioned between the source/drain pattern 150 and the gate structure GS. Specifically, the gate spacer 140 may be positioned between the source/drain pattern 150 and the gate dielectric layer 132 to be described later.

The gate spacer 140 is not positioned between the lower pattern BP and the channel pattern NS. The gate spacer 140 is not positioned between the channel patterns NS adjacent to each other in the third direction D3. However, example embodiments are not limited thereto, and the gate spacer 140 may be disposed between the channel patterns NS adjacent to each other in the third direction D3 or between the lower pattern BP and the channel pattern NS adjacent to each other in the third direction D3.

The gate spacer 140 may include at least one of for example, silicon nitride (SiN), silicon nitride oxide (SiON), silicon oxide (SiO₂), silicon carbonate nitride (SiOCN), silicon boronnitride (SiBN), silicon oxyboronitride (SiOBN), silicon oxycarbide (SiOC) and a combination thereof. Although it is illustrated that the gate spacer 140 is a single layer, it is only for convenience of explanation, and example embodiments are not limited thereto.

The capping layer 145 may be positioned on the gate structure GS and the gate spacer 140. An upper surface of the capping layer 145 may be on the same plane as an upper surface of the interlayer insulation layer 190. Unlike what is illustrated, the capping layer 145 may be positioned between the gate spacers 140. At this time, the upper surface of the capping layer 145 may be positioned on the same plane as an upper surface of the gate spacer 140.

The capping layer 145 may include at least one of, for example, silicon nitride (SiN), silicon nitride oxide (SiON), silicon (Si) carbonitride (SiCN), silicon carbonate nitride (SiOCN) and a combination thereof. The capping layer 145 may include a material having an etch selectivity with respect to the interlayer insulation layer 190.

The source/drain pattern 150 may be positioned on the lower pattern BP. The source/drain pattern 150 may be positioned on both sides of the gate structure GS. Therefore, the source/drain pattern 150 may be in contact with the side surface of the channel pattern NS. The source/drain pattern 150 may be connected to the channel pattern NS.

The source/drain pattern 150 may be positioned in a source/drain recess 150R having a depth along the third direction D3. The source/drain pattern 150 may fill the source/drain recess 150R. A bottom surface of the source/drain recess 150R may be defined by the lower pattern BP. A side surface of the source/drain recess 150R may be defined by the gate structure GS.

In cross-section, the source/drain pattern 150 may have a convex shape in the third direction D3. For example, the source/drain pattern 150 may have a convex shape in the third direction D3 from the upper surface of the uppermost the channel pattern NS. Therefore, an upper surface of the source/drain pattern 150 may be positioned at a higher level than the upper surface of the channel pattern NS. That is, the upper surface of the source/drain pattern 150 may be positioned farther from the upper surface of the substrate 100 than the upper surface of the channel pattern NS.

The source/drain patterns 150 may be epitaxial patterns formed by a selective epitaxial growth process using the active pattern AP as a seed. The channel pattern NS may be a portion of the active pattern AP extending between the source/drain patterns 150. The source/drain pattern 150 may serve as a source/drain of a transistor using the channel pattern NS as a channel region.

The source/drain pattern 150 may include a first source/drain pattern 151 and a second source/drain pattern 152.

The first source/drain pattern 151 may be positioned on the lower pattern BP. The first source/drain pattern 151 may have a shape surrounding a side surface and lower surface of the second source/drain pattern 152. The channel pattern NS may be in contact with the first source/drain pattern 151, and may not be in contact with the second source/drain pattern 152. Therefore, the first source/drain pattern 151 may be positioned between the channel pattern NS and the second source/drain pattern 152. However, example embodiments are not limited thereto, and at least a portion of the channel pattern NS may be in contact with the second source/drain pattern 152. In addition, the source/drain pattern 150 may be disposed of a single layer instead of being divided into the first source/drain pattern 151 and the second source/drain pattern 152.

An external surface of the first source/drain pattern 151 may be in contact with the channel pattern NS, the gate insulation layer 131, and the lower pattern BP. The external surface of the first source/drain pattern 151 may be disposed as an uneven and curved surface. For example, a portion of the external surface of the first source/drain pattern 151 contacting the channel pattern NS may have a concave or substantially flat shape in cross section. A portion of the external surface of the first source/drain pattern 151 in contact with the gate insulation layer 131 may have a convex shape. By further performing a process of selectively etching a dummy gate structure after forming the source/drain recess 150R, the shape of the source/drain recess 150R may become uneven. Accordingly, the shape of the external surface of the first source/drain pattern 151 may be determined.

The second source/drain pattern 152 may be positioned on the first source/drain pattern 151. The second source/drain pattern 152 may overlap the contact electrode CT in the third direction D3. The second source/drain pattern 152 may be in contact with the contact interface layer 230 to be described later. A side surface of the second source/drain pattern 152 may be flat in cross section.

The source/drain pattern 150 may include at least one of silicon (Si) and silicon germanium (SiGe). The germanium content of the first source/drain pattern 151 may be different from the germanium content of the second source/drain pattern 152. For example, the first source/drain pattern 151 may include of silicon germanium (SiGe) containing low-concentration germanium, and the second source/drain pattern 152 may include of silicon germanium (SiGe) containing high concentration germanium. However, the material of the source/drain pattern 150 is not limited thereto and may be variously changed.

The etch stop layer 185 may be positioned on the side surface of the gate spacer 140 and on the upper surface of the source/drain pattern 150. The etch stop layer 185 may be positioned between the gate structure GS and the contact electrode CT. The etch stop layer 185 may be positioned between the interlayer insulation layer 190 and the source/drain pattern 150. For example, on the cross-section disposed by the first direction D1 and the third direction D3, the etch stop layer 185 may include an extension portion positioned on the side surface of the gate spacer 140, and a protrusion portion extending from the extension portion and positioned between the interlayer insulation layer 190 and the source/drain pattern 150, but example embodiments are not limited thereto.

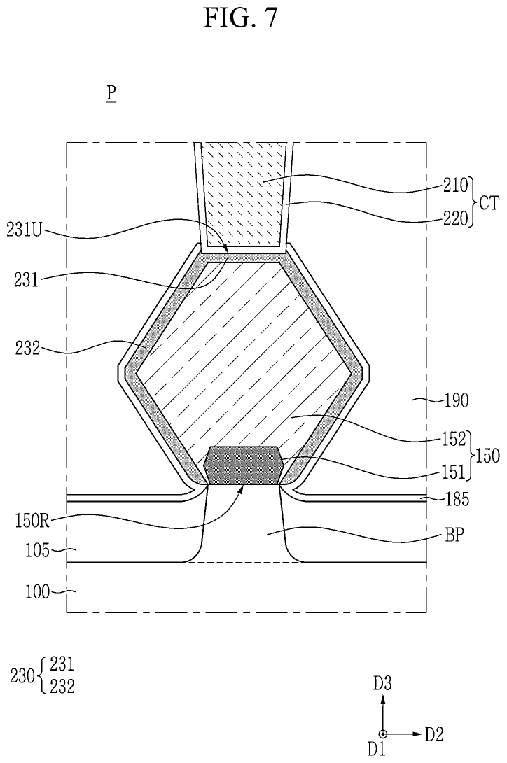

In addition, as shown in FIG. 7, on the cross-section disposed by the second direction D2 and the third direction D3, the etch stop layer 185 may be positioned on both sides of the source/drain pattern 150. The etch stop layer 185 may surround at least a portion of the source/drain pattern 150.

The etch stop layer 185 may include a material having an etch selectivity with respect to the interlayer insulation layer 190 to be described later. In addition, the etch stop layer 185 may include a material having an etch selectivity with respect to the source/drain pattern 150 to be described later. The etch stop layer 185 may include at least one of for example, silicon nitride (SiN), silicon nitride oxide (SiON), silicon carbonate nitride (SiOCN), silicon boron nitride (SiBN), silicon oxyboronitride (SiOBN), silicon oxycarbide (SiOC) and a combination thereof.

The interlayer insulation layer 190 may be positioned on the etch stop layer 185. The interlayer insulation layer 190 may be positioned on the source/drain pattern 150. The interlayer insulation layer 190 may not cover the upper surface of the capping layer 145. The interlayer insulation layer 190 may be positioned between the contact electrode CT and the etch stop layer 185. In addition, as shown in FIG. 7, on the cross-section disposed by the first direction D1 and the third direction D3, the interlayer insulation layer 190 may be positioned on both sides of the etch stop layer 185. The interlayer insulation layer 190 may surround the etch stop layer 185.

The interlayer insulation layer 190 may include at least one of for example, silicon oxide (Si02), silicon nitride (SiN), silicon nitride oxide (SiON), and low dielectric constant (low-k) material. The low dielectric constant (low-k) material may include, for example, polyimide nanofoams, such as Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride silicate glass), polypropylene oxide, CDO (Carbon Doped silicon Oxide), OSG (Organo silicate glass), SiLK, Amorphous Fluorinated Carbon, silica aerogels, silica xerogels, mesoporous silica or combinations thereof, but example embodiments are not limited thereto.

The contact electrode CT may be positioned on the source/drain pattern 150. For example, the contact electrode CT may be positioned on the contact interface layer 230 positioned on the source/drain pattern 150. The contact electrode CT may be electrically connected to the source/drain pattern 150. The contact electrode CT may pass through at least one interlayer insulation layer 190. The contact electrode CT may have a shape in which a width decreases toward the substrate 100 due to a high aspect ratio. For example, a first width W1 of a portion of the contact electrode CT overlapping the interlayer insulation layer 190 in the first direction D1 may be larger than a second width W2 of a portion of the contact electrode CT overlapping the second source/drain pattern 152 in the first direction D1.

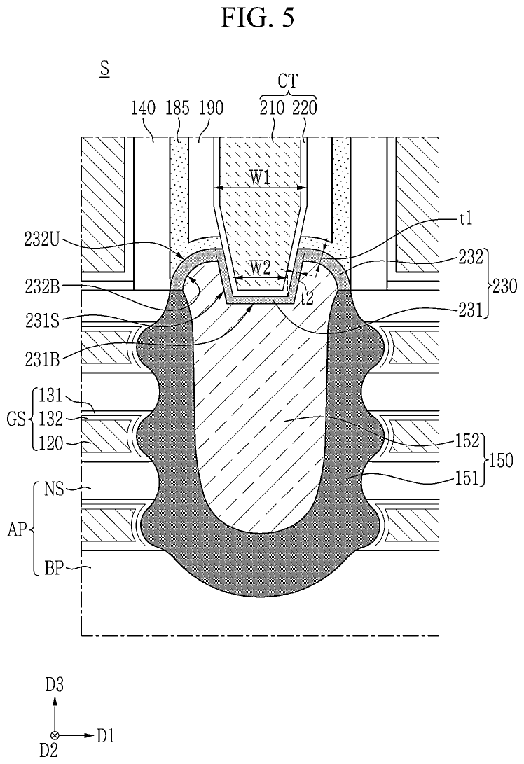

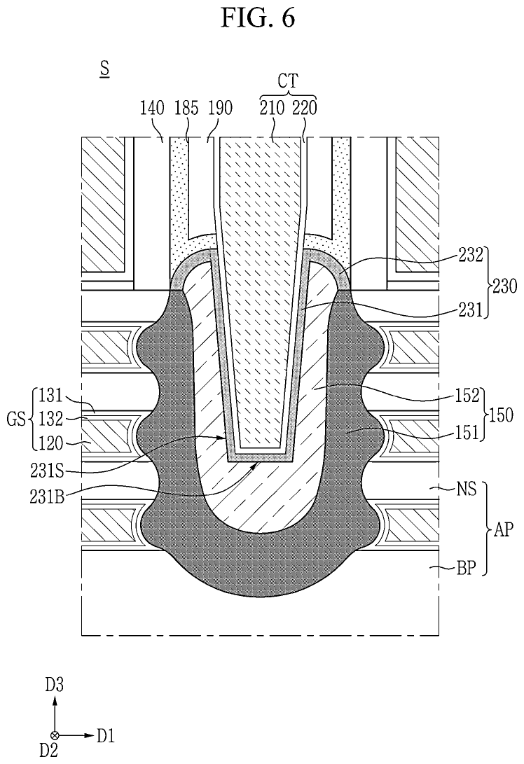

As shown in FIG. 5, a lower surface of the contact electrode CT may be positioned at a lower level than the upper surface of the uppermost the channel pattern NS among the channel patterns NS. However, example embodiments are not limited thereto, and the lower surface of the contact electrode CT may be higher than or equal to a lower surface of the uppermost channel pattern among the channel patterns NS. Alternatively, as shown in FIG. 6, the lower surface of the contact electrode CT may be positioned between a lower surface of the lowermost channel pattern and the lower surface of the uppermost channel pattern among the channel pattern NS.

The contact electrode CT may include a conductive pattern 210 and a barrier pattern 220 surrounding the conductive pattern 210.

The conductive pattern 210 may include at least one of for example, a metal, a metal alloy, a conductive metal nitride, a conductive metal carbide, a conductive metal oxide, a conductive metal carbonitride, and two-dimensional (2D) material.

The barrier pattern 220 may cover side surfaces and a lower surface of the conductive pattern 210. The barrier pattern 220 may include metal, metal alloy, conductive metal nitride. The metal may include at least one of titanium (Ti), tantalum (Ta), tungsten W, nickel (Ni), cobalt (Co) and platinum (Pt). The conductive metal nitride may include at least one of titanium nitride (TiN), tantalum nitride (TaN), tungsten nitride (WN), nickel nitride (NiN), cobalt nitride (CoN) and platinum nitride (PtN).

It is illustrated that the contact electrode CT is a double layer including the conductive pattern 210 and the barrier pattern 220, but it is only for convenience of description, and example embodiments are not limited thereto.

The contact interface layer 230 may be positioned on the source/drain pattern 150. The contact interface layer 230 may be positioned between the source/drain pattern 150 and the contact electrode CT, between the source/drain pattern 150 and the etch stop layer 185, and between the source/drain pattern 150 and the interlayer insulation layer 190. The contact interface layer 230 may surround a portion of the contact electrode CT recessed into the source/drain pattern 150. The contact interface layer 230 may extend along the upper surface of the source/drain pattern 150. The contact interface layer 230 may be in contact with the contact electrode CT and the source/drain pattern 150, respectively. Details of the contact interface layer 230 will be described later with reference to FIG. 5 to FIG. 7.

A semiconductor device according to an embodiment may further include an upper wiring structure 300.

The contact electrode CT may be position on the upper wiring structure 300. The upper wiring structure 300 may include upper wires 320 and an upper wire insulation layer 310.

The upper wire insulation layer 310 may be positioned on the etch stop layer 185, the interlayer insulation layer 190, and the capping layer 145. The upper wire insulation layer 310 may cover upper surfaces of the contact electrode CT.

The upper wires 320 may be positioned in the upper wire insulation layer 310. The upper wires 320 may pass through at least a portion of the upper wire insulation layer 310. The upper wires 320 may be electrically connected to the contact electrode CT. Upper surfaces of the upper wires 320 may be positioned on the substantially same level as an upper surface of the upper wire insulation layer 310. That is, the upper surfaces of the upper wires 320 may be at the same or substantially the same height as the upper surface of the upper wire insulation layer 310 with respect to the first surface 100a of the substrate 100.

The upper wire insulation layer 310 may include at least one of for example, silicon oxide (SiO₂), silicon nitride (SiN), silicon nitride oxide (SiON), or low dielectric layers. The upper wires 320 may include at least one of metal and conductive metal nitride.

Hereinafter, a semiconductor device according to an embodiment is described with reference to FIG. 5 to FIG. 7.

FIG. 5 illustrates an enlarged cross-sectional view of region “S” of FIG. 2. FIG. 6 is an enlarged cross-sectional view of a semiconductor device according to some embodiments, corresponding to region S of FIG. 2. FIG. 7 is an enlarged cross-sectional view of region “P” of FIG. 4.

Referring to FIG. 5 to FIG. 7, as described above, the contact interface layer 230 may be positioned on the source/drain pattern 150. The contact interface layer 230 may be positioned between the source/drain pattern 150 and the contact electrode CT, between the source/drain pattern 150 and the etch stop layer 185, and between the source/drain pattern 150 and the interlayer insulation layer 190.

The contact interface layer 230 may include a first region 231, a second region 232. The first region 231 of the contact interface layer 230 may be integrally formed with the second region 232 of the contact interface layer 230. The first region 231 of the contact interface layer 230 may be directly connected.

The first region 231 of the contact interface layer 230 may be positioned between the source/drain pattern 150 and the contact electrode CT. For example, the first region 231 may be positioned between the second source/drain pattern 152 and the contact electrode CT. The first region 231 may surround at least a portion of the contact electrode CT. The first region 231 may surround the contact electrode CT recessed into the source/drain pattern 150. The first region 231 may extend along a profile of the contact electrode CT. The first region 231 may be electrically connected to the contact electrode CT. The first region 231 may be electrically connected to the source/drain pattern 150. That is, the contact electrode CT and the source/drain pattern 150 may be electrically connected by the first region 231.

The first region 231 may be recessed into the source/drain pattern 150. The first region 231 may have a three-dimensional pocket shape. The first region 231 may have a convex shape toward the substrate 100, but example embodiments are not limited thereto.

As the first region 231 is recessed into the source/drain pattern 150, as shown in FIG. 5, a lower surface 231B of the first region 231 may be positioned at a lower level than the upper surface of the uppermost channel pattern among the channel patterns NS. However, example embodiments are not limited thereto, and the lower surface 231B of the first region 231 may be higher than or equal to the lower surface of the uppermost channel pattern among the channel patterns NS. Alternatively, as shown in FIG. 6, the lower surface 231B of the first region 231 may be positioned between the lower surface of the lowermost channel pattern and the lower surface of the uppermost channel pattern among the channel patterns NS.

The first region 231 may include an internal surface and an external surface. An internal surface of the first region 231 may be in contact with the contact electrode CT. An external surface 231S of the first region 231 may be in contact with the source/drain pattern 150. For example, the lower surface 231B of the first region 231 and the external surface 231S of the first region 231 may be in contact with the source/drain pattern 150.

The second region 232 of the contact interface layer 230 may extend from the first region 231 in the first direction D1. The second region 232 may extend from the first region 231 toward the gate structure GS. In addition, the second region 232 may extend along the upper surface of the source/drain pattern 150. For example, the second region 232 may extend along an upper surface of the second source/drain pattern 152, to be in contact with the first source/drain pattern 151. Accordingly, the second region 232 may be electrically connected to the first region 231. The second region 232 may be electrically connected to the source/drain pattern 150. That is, by the second region 232, an area where the contact electrode CT and the source/drain pattern 150 are electrically connected may increase and contact resistance may decrease.

The second region 232 may be positioned between the source/drain pattern 150 and the etch stop layer 185. For example, the second region 232 may be positioned between the second source/drain pattern 152 and the etch stop layer 185. The second region 232 may be in contact with the source/drain pattern 150 and the etch stop layer 185, respectively. The second region 232 may be positioned between the source/drain pattern 150 and the interlayer insulation layer 190. That is, the second region 232 may overlap the etch stop layer 185 in the third direction D3 (the thickness direction of the substrate 100). The second region 232 may overlap the interlayer insulation layer 190 in the third direction D3 (the thickness direction of the substrate 100). The second region 232 may extend with a constant thickness along a profile of the second source/drain pattern 152. In addition, the second region 232 may be positioned between adjacent gate structures. For example, the second region 232 may be positioned between adjacent gate spacers 140. The second region 232 may be in contact with the gate spacer 140.

The second region 232 may include lower surface in contact with the source/drain pattern 150 and upper surface in contact with the etch stop layer 185. A lower surface 232B of the second region 232 may be in contact with the second source/drain pattern 152. An upper surface 232U of the second region 232 may be in contact with the etch stop layer 185.

The upper surface 232U of the second region 232 may be positioned at a higher level than the upper surface of the channel pattern NS. The upper surface 232U of the second region 232 may be positioned at a higher level than an upper surface of the first source/drain pattern 151. That is, an upper surface of the second region 232 may be positioned farther from the upper surface of the substrate 100 than the upper surface of the channel pattern NS.

As shown in FIG. 7, on the cross-section disposed by the third direction D3 and the second direction D2, the contact interface layer 230 may surround the source/drain pattern 150. For example, the second region 232 of the contact interface layer 230 may surround at least a portion of the second source/drain pattern 152, by covering the side surface of the second source/drain pattern 152. In addition, the first region 231 of the contact interface layer 230 may surround a remaining portion of the second source/drain pattern 152, by covering the upper surface of the second source/drain pattern 152. That is, the second source/drain pattern 152 may be surrounded by the contact interface layer 230. However, example embodiments are not limited thereto, and the contact interface layer 230 may surround only at least a portion of the second source/drain pattern 152.

The second region 232 may have a convex shape toward the third direction D3 (e.g., a direction away from the substrate 100). For example, the lower surface 232B of the second region 232 and the upper surface 232U of the second region 232 may have a convex shape toward a direction away from the substrate 100, respectively. However, example embodiments are not limited thereto, and the lower surface 232B of the second region 232 and the upper surface 232U of the second region 232 may have a planar shape.

A second thickness t1 of the second region 232 of the contact interface layer 230 may be greater than a first thickness t2 of the first region 231. The contact interface layer 230 may be conformally disposed along the profile of the second source/drain pattern 152, and at this time, the thickness of the contact interface layer 230 may mean a thickness in a direction away from the second source/drain pattern 152.

The first region 231 and the second region 232 may include metal-silicide. For example, the first region 231 and the second region 232 of the contact interface layer 230 may include at least one of titanium-silicide, tantalum-silicide, tungsten-silicide, nickel-silicide, and cobalt-silicide, but example embodiments are not limited thereto. Alternatively, the first region 231 and the second region 232 may include metal material. For example, the first region 231 and the second region 232 may include at least one of titanium (Ti) and titanium nitride (TiN).

The first region 231 and the second region 232 of the contact interface layer 230 may include the same material. In this case, the first region 231 and the second region 232 of the contact interface layer 230 may be integrally formed to be in contact with each other without an interface.

However, but example embodiments are not limited thereto, the first region 231 and the second region 232 of the contact interface layer 230 may include different materials. For example, when the first region 231 includes at least one of titanium (Ti) and titanium nitride (TiN), the second region 232 may include at least one of titanium-silicide, tantalum-silicide, tungsten-silicide, nickel-silicide, and cobalt-silicide.

In a semiconductor device according to an embodiment, in order to prevent parasitic capacitance generated between the gate structure GS and the contact electrode CT or a short circuit between the gate structure GS and the contact electrode CT, a width of the contact electrode CT may be smaller than a width between the gate structures GS. That is, as the width of the contact electrode CT decreases, the short circuit between the contact electrode CT and the gate structure GS may be prevented. However, as the width of the contact electrode CT decreases, contact resistance between the contact electrode CT and the second source/drain pattern 152 may increase.

The contact interface layer 230 of a semiconductor device according to an embodiment may include the first region 231 positioned between the contact electrode CT and the source/drain pattern 150 and the second region 232 extending from a side of the first region 231 along the upper surface of the source/drain pattern 150. Accordingly, compared to the case where only the first region 231 of the contact interface layer 230 is positioned between the contact electrode CT and the source/drain pattern 150, the contact area between the contact electrode CT and the source/drain pattern 150 may be increased. Therefore, the contact resistance between the contact electrode CT and the source/drain pattern 150 is reduced, thereby securing reliability of the semiconductor device.

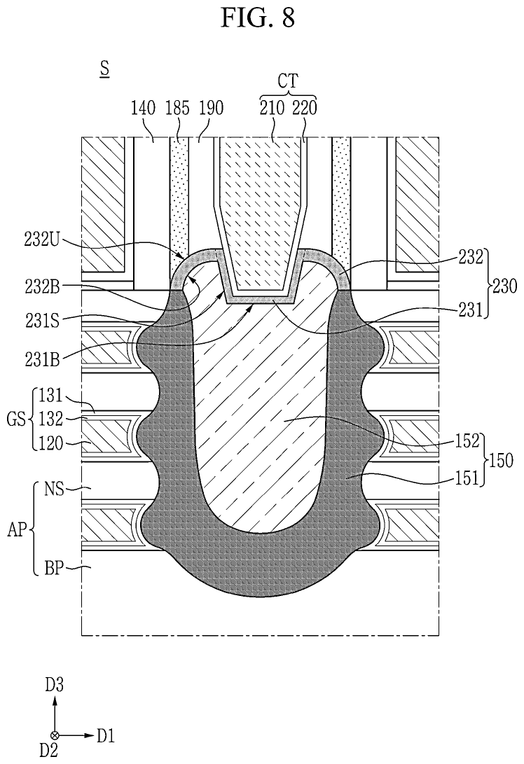

Hereinafter, a semiconductor device according to some embodiments will be described with reference to FIG. 8.

FIG. 8 is an enlarged cross-sectional view of a semiconductor device according to some embodiments, corresponding to region S of FIG. 2.

Since the embodiment shown in FIG. 8 has the same or substantially the same parts as the embodiment shown in FIG. 1 to FIG. 7, a description thereof will be omitted and differences will be mainly described. In this embodiment, the shape of the etch stop layer 185 is different from that of the previous embodiment, which will be described below.

A semiconductor device according to an embodiment includes the substrate 100, the active pattern AP, the gate structure GS, the source/drain pattern 150, the etch stop layer 185, the interlayer insulation layer 190, the contact electrode CT, and the contact interface layer 230.

In the previous embodiment, the etch stop layer 185 may be positioned between the interlayer insulation layer 190 and the source/drain pattern 150. For example, on the cross-section disposed by the first direction D1 and the third direction D3, the etch stop layer 185 may include the extension portion positioned on the side surface of the gate spacer 140, and the protrusion portion extending from the extension portion and positioned between the interlayer insulation layer 190 and the source/drain pattern 150.

Referring to FIG. 8, the etch stop layer 185 of a semiconductor device according to some embodiments may extend in the third direction D3. A portion of the etch stop layer 185 may not be positioned between the interlayer insulation layer 190 and the source/drain pattern 150. For example, the etch stop layer 185 may include the extension portion positioned on the side surface of the gate spacer 140, and may not include the protrusion portion positioned between the interlayer insulation layer 190 and the source/drain pattern 150.

Accordingly, the interlayer insulation layer 190 may be in contact with the contact interface layer 230. For example, the upper surface 232U of the second region 232 of the contact interface layer 230 may be in contact with the interlayer insulation layer 190 and the etch stop layer 185.

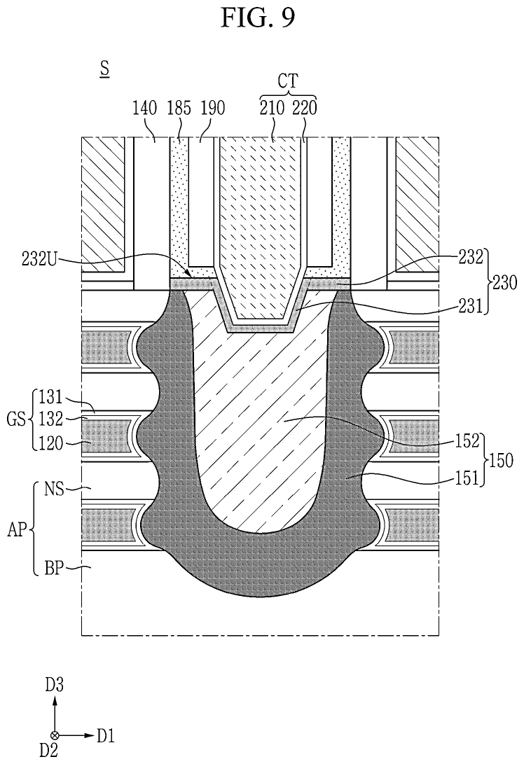

Hereinafter, a semiconductor device according to some embodiments is described with reference to FIG. 9.

FIG. 9 is an enlarged cross-sectional view of a semiconductor device according to some embodiments, corresponding to region S of FIG. 2.

Since the embodiment shown in FIG. 9 has the same or substantially the same parts as the embodiment shown in FIG. 1 to FIG. 7, a description thereof will be omitted and differences will be mainly described. In this embodiment, the shape of the source/drain pattern 150 and the contact interface layer 230 is different from that of the previous embodiment, which will be described below.

A semiconductor device according to an embodiment includes the substrate 100, the active pattern AP, the gate structure GS, the source/drain pattern 150, the etch stop layer 185, the interlayer insulation layer 190, the contact electrode CT, and the contact interface layer 230.

In the previous embodiment, the source/drain pattern 150 may have a convex shape in the third direction D3. For example, the source/drain pattern 150 may have a convex shape in the third direction D3 from the upper surface of the uppermost the channel pattern NS

In addition, the second region 232 may have a convex shape toward the third direction D3 (for example, an upper surface of the contact electrode CT). For example, the lower surface 232B of the second region 232 and the upper surface 232U of the second region 232 may have a convex shape toward the upper surface of the contact electrode CT, respectively.

Referring to FIG. 9, the upper surface of the source/drain pattern 150 of a semiconductor device according to some embodiments may have a planar shape. The upper surface of the source/drain pattern 150 may be positioned on the substantially same level as the upper surface of the channel pattern NS. However, example embodiments are not limited thereto, the upper surface of the source/drain pattern 150 may have a concave shape toward the substrate 100.

Accordingly, the upper surface 232U of the second region 232 and the lower surface 232B of the second region 232 may have a planar shape

The lower surface 232B of the second region 232 may be positioned on the substantially same level as the upper surface of the source/drain pattern 150. That is, the lower surface 232B of the second region 232 may be positioned on the substantially same level as the upper surface of the channel pattern NS. In this case, the upper surface of the second region 232 may be positioned at a higher level than the upper surface of the channel pattern NS. That is, the upper surface of the second region 232 may be positioned farther from the upper surface of the substrate 100 than the upper surface of the channel pattern NS.

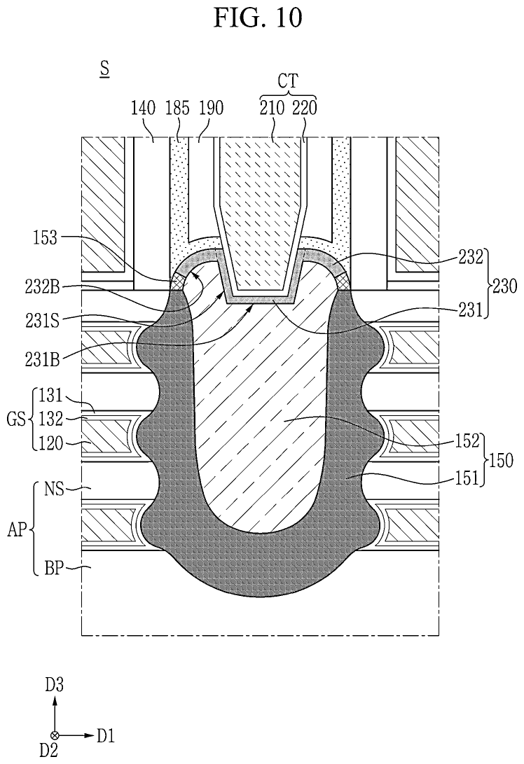

Hereinafter, a semiconductor device according to some embodiments will be described with reference to FIG. 10 to FIG. 12.

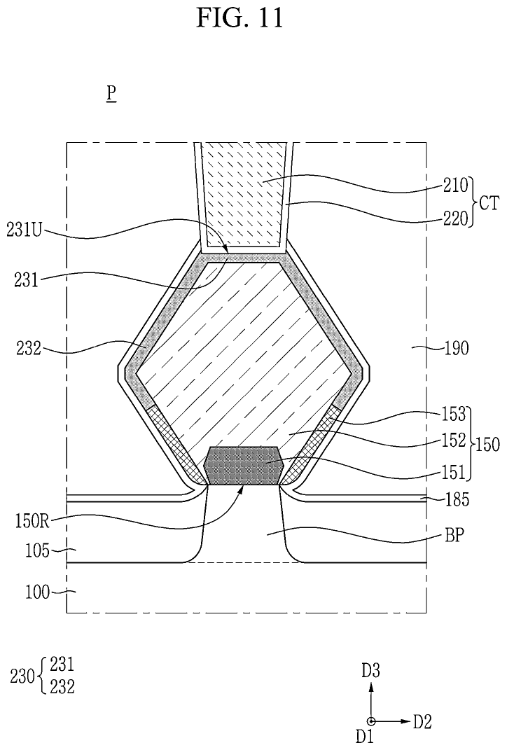

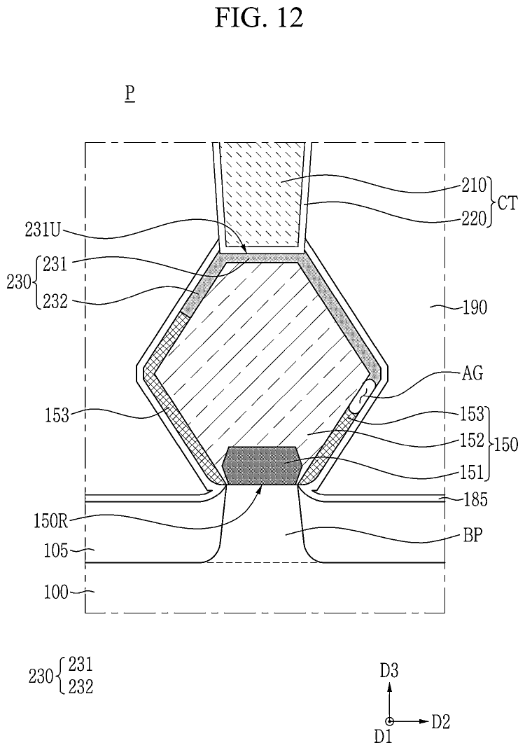

FIG. 10 is an enlarged cross-sectional view of a semiconductor device according to some embodiments, corresponding to region S of FIG. 2. FIG. 11 and FIG. 12 are enlarged cross-sectional views of a semiconductor device according to some embodiments, corresponding to region P of FIG. 4.

Since the embodiment shown in FIG. 10 to FIG. 12 has the same or substantially the same parts as the embodiment shown in FIG. 1 to FIG. 7, a description thereof will be omitted and differences will be mainly described. This embodiment is different from the previous embodiment in that the third source/drain pattern 153 or the air gap AG is further included, which will be described below.

A semiconductor device according to an embodiment includes the substrate 100, the active pattern AP, the gate structure GS, the source/drain pattern 150, the etch stop layer 185, the interlayer insulation layer 190, the contact electrode CT, the contact interface layer 230 and the third source/drain pattern 153.

In the previous embodiment, the source/drain pattern 150 may include the first source/drain pattern 151 and the second source/drain pattern 152.

The contact interface layer 230 may be positioned on the second source/drain pattern 152. The second region 232 of the contact interface layer 230 may extend along the upper surface of the source/drain pattern 150. For example, the second region 232 may extend along the upper surface of the second source/drain pattern 152, to entirely cover the upper surface of the second source/drain pattern 152. The second source/drain pattern 152 may be in contact with the first source/drain pattern 151.

Referring to FIG. 10 and FIG. 11, the source/drain pattern 150 of a semiconductor device according to some embodiments may further include the third source/drain pattern 153.

The third source/drain pattern 153 may be positioned on the upper surface of the second source/drain pattern 152. The third source/drain pattern 153 may be positioned between the etch stop layer 185 and the second source/drain pattern 152. That is, the third source/drain pattern 153 may overlap the etch stop layer 185 in the third direction D3. In addition, the third source/drain pattern 153 may overlap the interlayer insulation layer 190 in the third direction D3. The third source/drain pattern 153 may be positioned between adjacent gate structures GS. For example, the third source/drain pattern 153 may be positioned between the gate spacers 140. The third source/drain pattern 153 may be conformally disposed along the profile of the second source/drain pattern 152. At this time, the third source/drain pattern 153 may have a thickness of 0.5 nm to 4 nm, but example embodiments are not limited thereto.

The third source/drain pattern 153 may be positioned between the second region 232 and the first source/drain pattern 151. The third source/drain pattern 153 may be in contact with the first source/drain pattern 151 and the second region 232. Accordingly, at least a portion of the upper surface of the second source/drain pattern 152 may overlap the second region 232 in the third direction D3, and a remaining portion of the second source/drain pattern 152 may overlap the third source/drain pattern 153 in the third direction D3.

The third source/drain pattern 153 may include at least one of silicon (Si) and silicon germanium (SiGe). The germanium content of the third source/drain pattern 153 may be different from the germanium content of the first source/drain pattern 151 and the germanium content of the second source/drain pattern 152. The third source/drain pattern 153 may include a material having etch selectivity with respect to the second source/drain pattern 152. For example, the germanium content of the third source/drain pattern 153 may be greater than germanium content of the second source/drain pattern 152. For example, the germanium content of the second source/drain pattern 152 may be in a range of 50w % to 60w %, and the germanium content of the third source/drain pattern 153 may be 70 W % or more. That is, the germanium content of the third source/drain pattern 153 may be 10w % to 20w % greater than the germanium content of the second source/drain pattern 152. However, the material of the third source/drain pattern 153 is not limited thereto and may be variously changed.

Referring to FIG. 12, a semiconductor device according to some embodiments may further include the air gap AG.

The air gap AG may be positioned on the side surface of the second source/drain pattern 152. The air gap AG may be positioned between the etch stop layer 185 and the second source/drain pattern 152.

The air gap AG may be positioned between the second region 232 and the third source/drain pattern 153. For example, when the third source/drain pattern 153 is positioned on the first source/drain pattern 151, the air gap AG may be positioned between the second region 232 and the third source/drain pattern 153. The air gap AG may be in contact with the third source/drain pattern 153 and the second region 232.

The air gap AG is a region where no solid material is provided and may be a substantially empty space.

FIG. 12 illustrates that the air gap AG is in contact with the second source/drain pattern 152, but example embodiments are not limited thereto. For example, the air gap AG may be surrounded by the second region 232 of the contact interface layer 230.

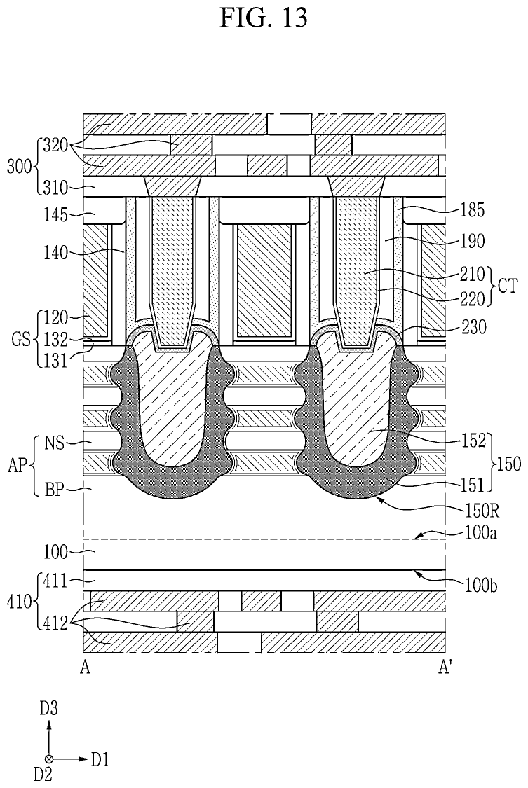

Hereinafter, a semiconductor device according to some embodiments will be described with reference to FIG. 13 to FIG. 15.

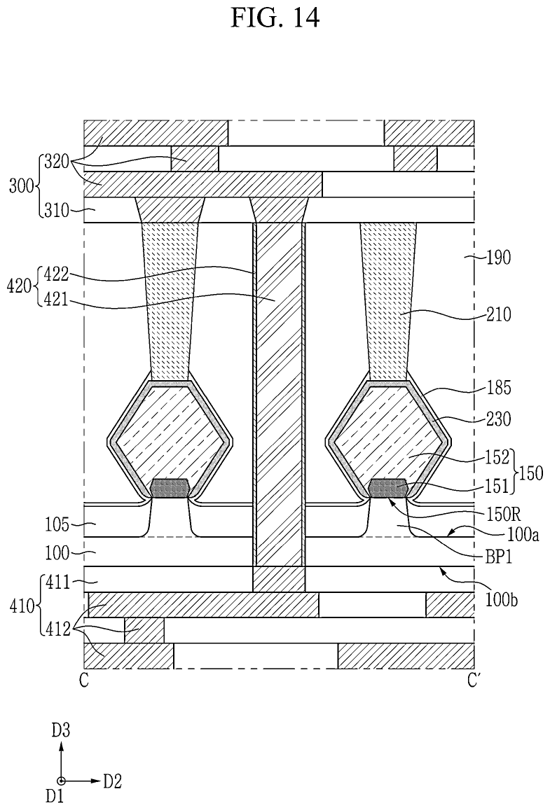

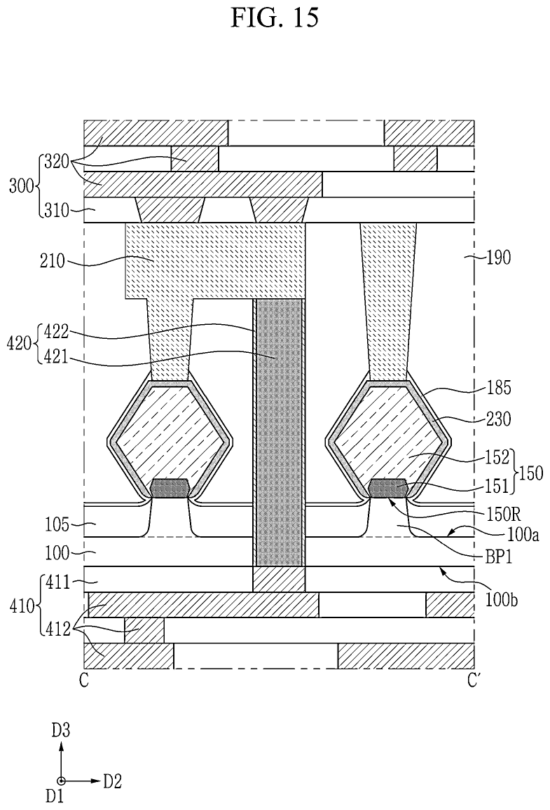

FIG. 13 is a cross-sectional view of a semiconductor device according to some embodiments, corresponding to a cross-sectional view taken along line A-A′ of FIG. 1. FIG. 14 and FIG. 15 are cross-sectional views of a semiconductor device according to some embodiments, corresponding to a cross-sectional view taken along C-C′ of FIG. 1.

Since the embodiment shown in FIG. 13 to FIG. 15 has the same or substantially the same parts as the embodiment shown in FIG. 1 to FIG. 7, a description thereof will be omitted and differences will be mainly described. This embodiment is different from the previous embodiment in that a lower wiring structure 410 and a through-via structure 420 are further included, which will be described below. For convenience of description, the barrier pattern of the contact electrode CT is not illustrated in FIG. 14 and FIG. 15.

A semiconductor device according to an embodiment includes the substrate 100, the active pattern AP, the gate structure GS, the source/drain pattern 150, the etch stop layer 185, the interlayer insulation layer 190, the contact electrode CT, the contact interface layer 230, the third source/drain pattern 153, the lower wiring structure 410, and the through via structure 420.

Referring to FIG. 13 to FIG. 15, a semiconductor device according to some embodiments may further include the lower wiring structure 410 and the through via structure 420.

The lower wiring structure 410 may be positioned on the second surface 100b of the substrate 100. The lower wiring structure 410 may be, for example, a power delivery network that supplies voltage (e.g., a power supply voltage, etc.) to the source/drain pattern 150.

The lower wiring structure 410 may include lower wires 411 and a lower wire insulation layer 412.

The lower wires 411 may be positioned on the second surface 100b of the substrate 100. The lower wires 411 may include metal (e.g., copper). The lower wires 411 may be electrically connected to the through via structure 420 to be described later.

The lower wire insulation layer 412 may be positioned on the second surface 100b of the substrate 100. The lower wire insulation layer 412 may cover the lower wiring structure 410. That is, the lower wire insulation layer 412 may cover the lower wires 411, and the lower wires 411 may be positioned within the lower wire insulation layer 412. The lower wire insulation layer 412 may include at least one of for example, silicon oxide (SiO₂), silicon nitride (SiN), silicon nitride oxide (SiON), or low dielectric layers.

The through via structure 420 may be positioned between the source/drain patterns 150. The through via structure 420 may pass through the interlayer insulation layer 190 positioned between the source/drain patterns 150. The through via structure 420 includes a through via 421 and an insulation pattern 422.

The through via 421 may be positioned between the source/drain patterns 150. The through via 421 may pass through the interlayer insulation layer 190 positioned between the source/drain patterns 150.

For example, as shown in FIG. 14, the through via 421 may be positioned between the upper wiring structure 300 and the lower wiring structure 410. The through via 421 may extend from the upper wiring structure 300 to the lower wiring structure 410 in the third direction D3. A lower surface of the through via 421 may be connected to the lower wiring structure 410. An upper surface of the through via 421 may be connected to the upper wiring structure 300. The through via 421 may pass through the substrate 100.

Alternatively, as shown in FIG. 15, the through via 421 may be positioned between the contact electrode CT and the lower wiring structure 410. The through via 421 may extend from the contact electrode CT to the lower wiring structure 410 in the third direction D3. The lower surface of the through via 421 may be connected to the lower wiring structure 410, but example embodiments are not limited thereto. An upper surface of the through via 421 may be connected to the contact electrode CT.

The through via 421 may be connected to at least one source/drain pattern 150. FIG. 14 and FIG. 15 illustrate that the through vias 421 are connected to one source/drain pattern 150, but example embodiments are not limited thereto.

The source/drain pattern 150 and the lower wiring structure 410 may be electrically connected to each other through the through via 421. That is, a voltage (e.g., a power voltage, etc.) may be applied from the lower wiring structure 410 to the source/drain pattern 150 through the through via 421.

The insulation pattern 422 may be positioned on both sides of the through via 421. The insulation pattern 422 may be in contact with a side surface of the substrate 100. A first end of the insulation pattern 422 may be in contact with the interlayer insulation layer 190. A second end of the insulation pattern 422 may be in contact with the lower wiring structure 410.

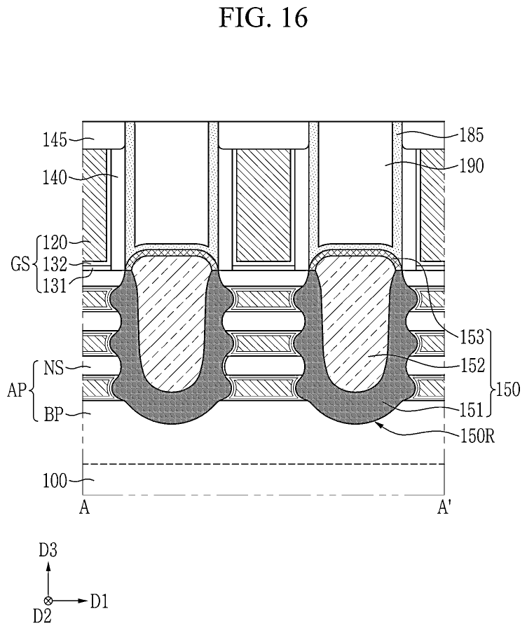

Hereinafter, referring to FIG. 16 to FIG. 29, a method of manufacturing a semiconductor device according to an embodiment is described.

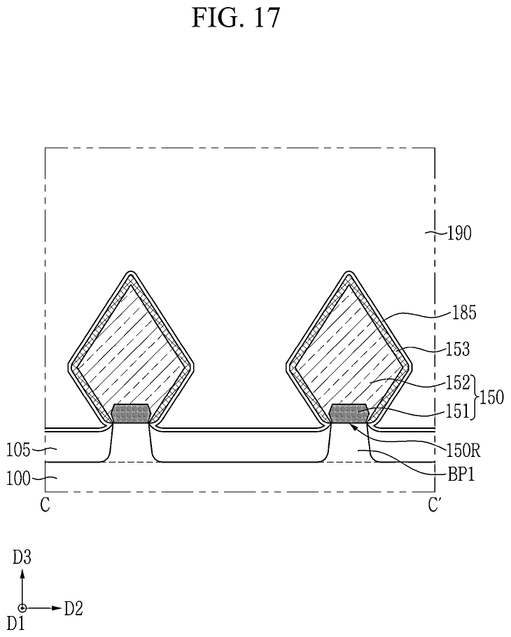

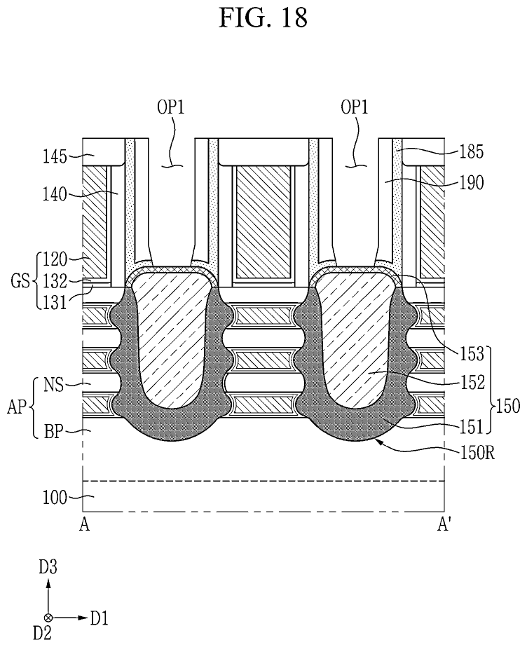

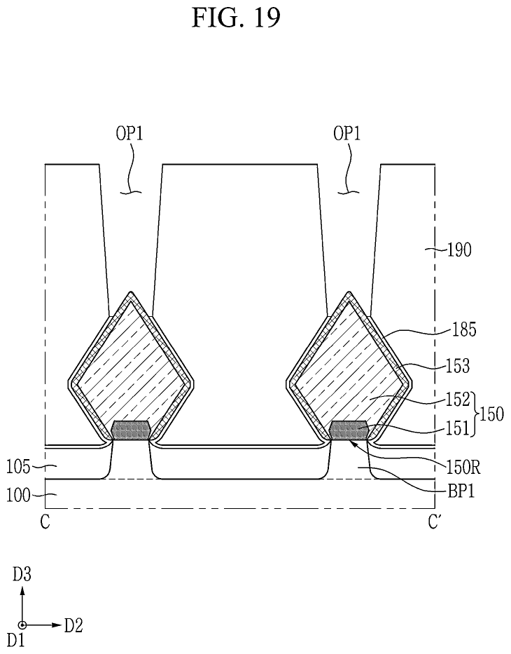

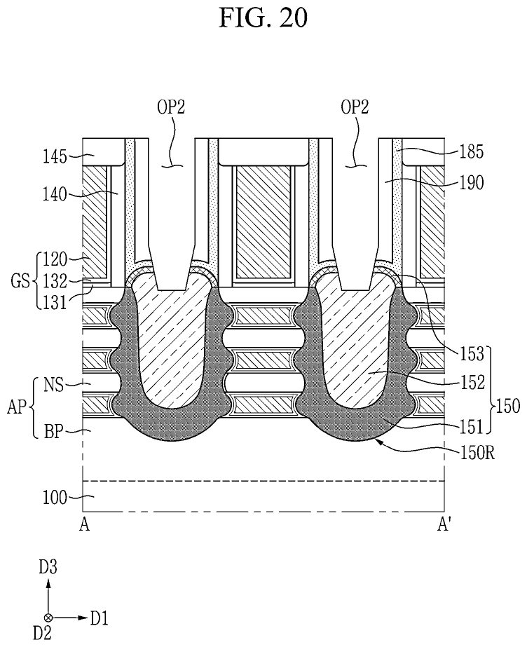

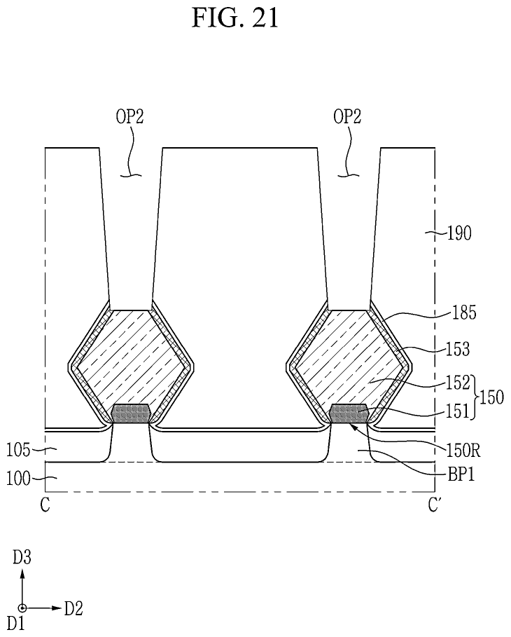

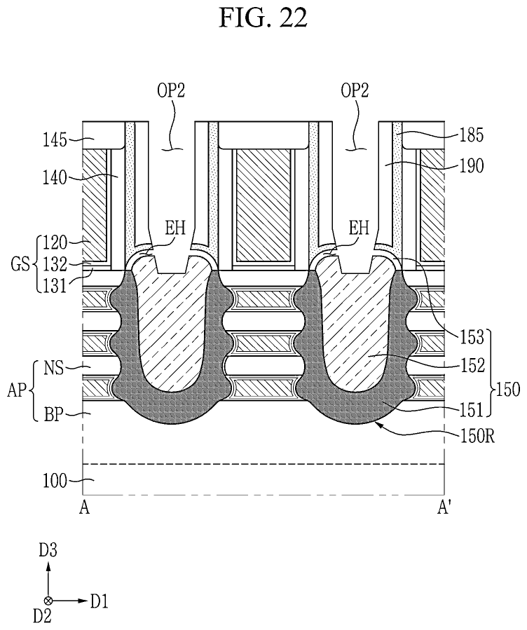

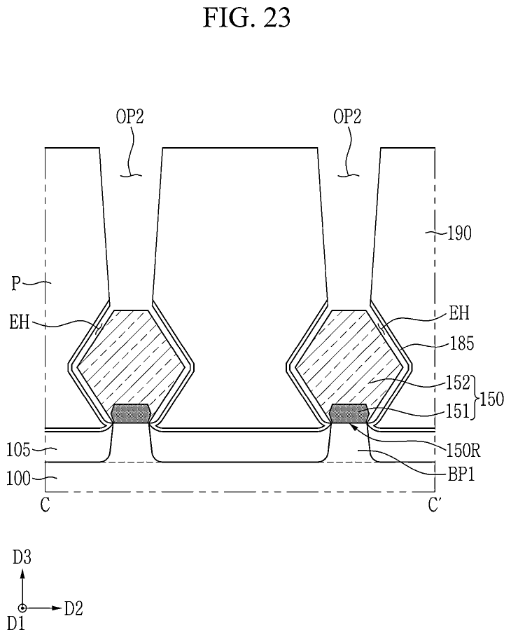

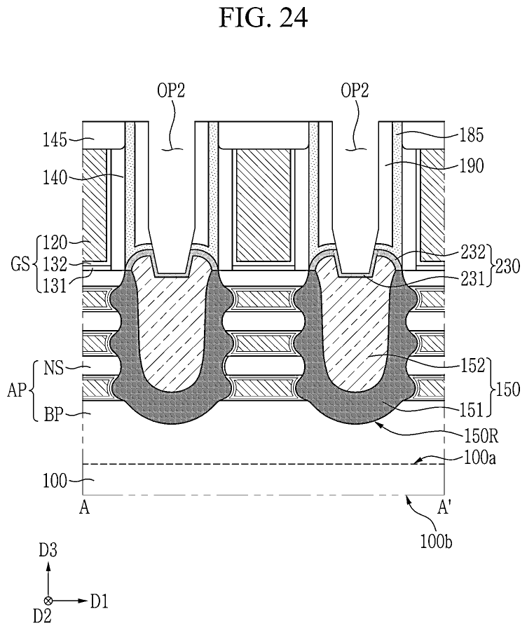

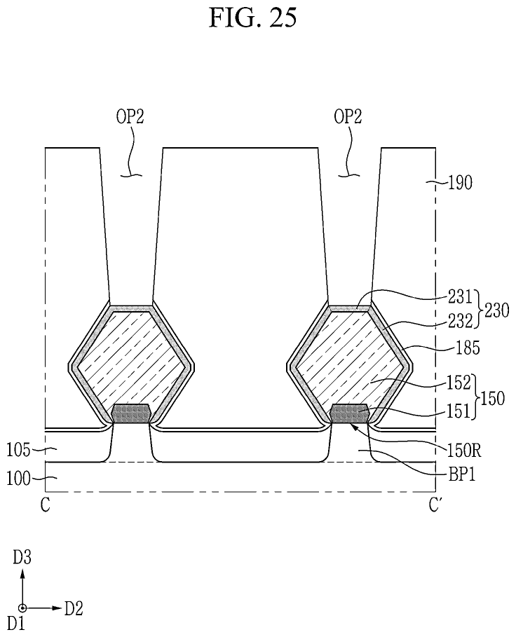

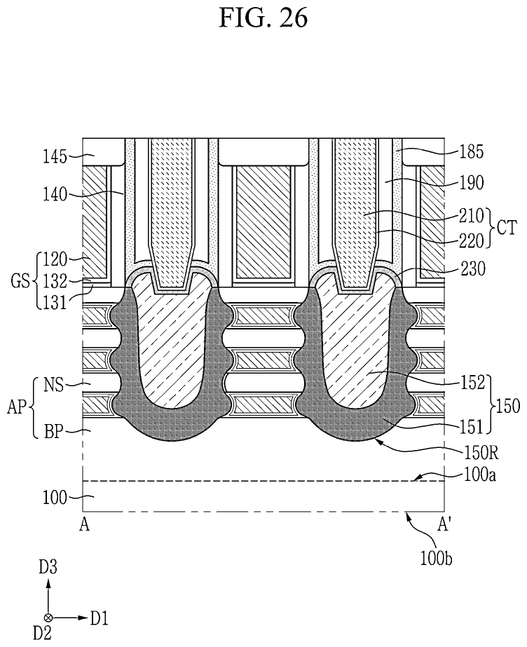

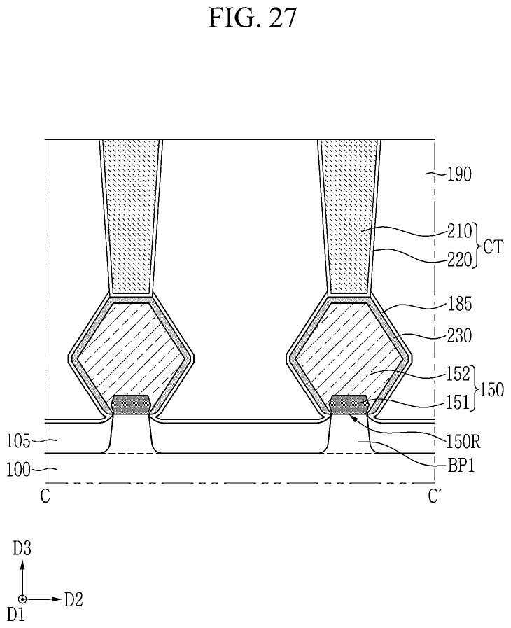

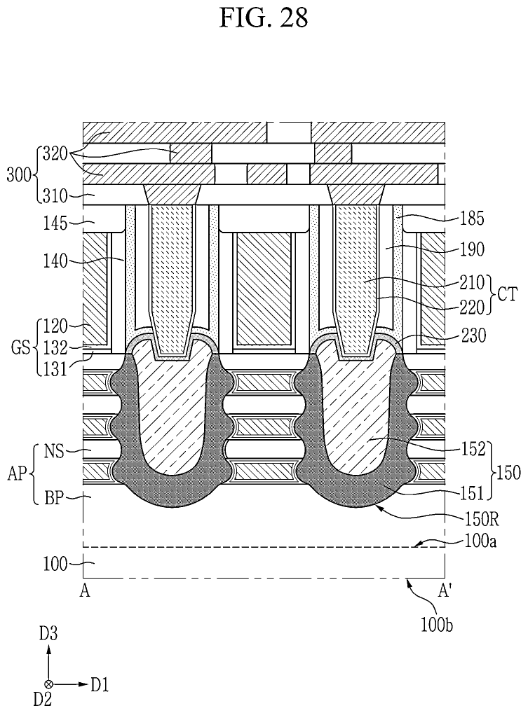

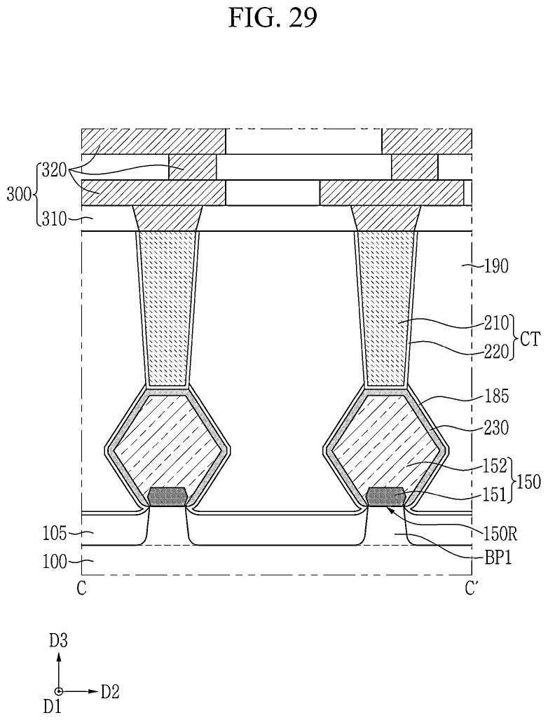

FIG. 16, FIG. 18, FIG. 20, FIG. 22, FIG. 24, FIG. 26, FIG. 28 are cross-sectional views showing intermediate stages of a method of manufacturing a semiconductor device according to an embodiment, corresponding to a cross-sectional view taken along line A-A′ of FIG. 1. FIG. 17, FIG. 19, FIG. 21, FIG. 23, FIG. 25, FIG. 27, FIG. 29 are cross-sectional views showing intermediate stages of a method of manufacturing a semiconductor device according to an embodiment, corresponding to a cross-sectional view taken along line C-C′ of FIG. 1.

As shown in FIG. 16 and FIG. 17, a method for forming a semiconductor device according to an embodiment may include forming the active pattern AP, the channel pattern NS, the field insulation layer 105, the gate structure GS, the source/drain pattern 150, the capping layer 145, the etch stop layer 185, and the interlayer insulation layer 190 on the substrate 100.

The substrate 100 may be silicon-on-insulator (SOI) or bulk silicon. Alternatively, the substrate 100 may be a silicon substrate, or may include other materials, for example, silicon germanium (SiGe), SGOI (silicon germanium on insulator), indium antimonide, lead tellurium compound, indium arsenic, indium phosphide, gallium arsenide, or gallium antimonide, but example embodiments are not limited thereto.

The lower pattern BP may be formed on the substrate 100, and a gate sacrificial pattern and the channel pattern NS may be formed on the lower pattern BP. The lower pattern BP, the gate sacrificial pattern, and the channel pattern NS may be formed by patterning an upper portion of the substrate 100.

Specifically, the gate sacrificial patterns and semiconductor patterns are alternately stacked on the lower pattern BP, to form a main the gate sacrificial pattern. The main the gate sacrificial pattern may be formed by patterning an uppermost the gate sacrificial pattern. Subsequently, the source/drain recess 150R may be formed by removing the alternately stacked gate sacrificial patterns and semiconductor patterns using the main the gate sacrificial pattern as a mask.

As the source/drain recess 150R is formed, the channel pattern NS may be formed as the semiconductor pattern is separated. The source/drain recesses 150R may be positioned on both sides of the channel pattern NS.

Subsequently, the source/drain pattern 150 is formed in the source/drain recess 150R. The source/drain pattern 150 may be formed using an epitaxial growth method. At this time, an inner wall of the source/drain recess 150R may be used as a seed.

The source/drain pattern 150 may include the first source/drain pattern 151, the second source/drain pattern 152, and the third source/drain pattern 153. First, after forming the first source/drain pattern 151 in the source/drain recess 150R, the second source/drain pattern 152 may be formed on the first source/drain pattern 151.

Subsequently, the third source/drain pattern 153 may be formed on the second source/drain pattern 152. The third source/drain pattern 153 may be conformally formed along the upper surface of the second source/drain pattern 152.

The source/drain pattern 150 may include at least one of silicon (Si) and silicon germanium (SiGe). The germanium content of the first source/drain pattern 151 may be different from the germanium content of the second source/drain pattern 152. For example, the first source/drain pattern 151 may be formed of silicon germanium (SiGe) containing low-concentration germanium, and the second source/drain pattern 152 may be formed of silicon germanium (SiGe) containing high concentration germanium. However, the material of the source/drain pattern 150 is not limited thereto and may be variously changed.

In addition, the third source/drain pattern 153 may include at least one of silicon (Si) and silicon germanium (SiGe).

The germanium content of the third source/drain pattern 153 may be different from the germanium content of the first source/drain pattern 151 and the germanium content of the second source/drain pattern 152. For example, the germanium content of the third source/drain pattern 153 may be greater than germanium content of the second source/drain pattern 152.

The third source/drain pattern 153 may include a material having etch selectivity with respect to the second source/drain pattern 152. For example, the germanium content of the third source/drain pattern 153 may be greater than germanium content of the second source/drain pattern 152. For example, the germanium content of the second source/drain pattern 152 may be in a range of 50w % to 60w %, and the germanium content of the third source/drain pattern 153 may be 70W % or more. That is, the germanium content of the third source/drain pattern 153 may be 10w % to 20w % greater than the germanium content of the second source/drain pattern 152. However, the material of the third source/drain pattern 153 is not limited thereto and may be variously changed.

However, the material of the third source/drain pattern 153 is not limited thereto and may be variously changed.

Subsequently, the etch stop layer 185 and the interlayer insulation layer 190 are sequentially formed to cover the source/drain pattern 150. The etch stop layer 185 may be conformally formed to cover an upper surface of the third source/drain pattern 153 and the side surface of the gate spacer 140.

The etch stop layer 185 may include a material having an etch selectivity with respect to the interlayer insulation layer 190. The etch stop layer 185 may include at least one of for example, silicon nitride (SiN), silicon oxynitride (SiON), silicon oxycarbonitride (SiOCN), silicon boronnitride (SiBN), silicon oxyboronitride (SiOBN), silicon oxycarbide (SiOC) and a combination thereof.

The interlayer insulation layer 190 may include at least one of for example, silicon oxide, silicon nitride (SiN), silicon oxynitride (SiON) and low dielectric constant (low-k) material. However, example embodiments are not limited thereto.

FIG. 16 and FIG. 17 illustrate that the etch stop layer 185 is conformally formed along the upper surface of the third source/drain pattern 153, but example embodiments are not limited thereto. For example, the interlayer insulation layer 190 may be formed after removing the etch stop layer 185 positioned on the top surface of the third source/drain pattern 153. In this case, the interlayer insulation layer 190 may be in contact with the upper surface of the third source/drain pattern 153.

Subsequently, the gate sacrificial pattern may be removed, and the gate structure GS may be formed in a space where the gate sacrificial pattern is removed. First, a gate insulating film may be formed, and a gate electrode may be formed on the gate insulating film. The gate electrode may be formed using an atomic layer deposition (ALD) process, a chemical vapor deposition (CVD) process, or the like.

Accordingly, the gate structure GS may cover the upper surface of the channel pattern NS, and may cover the both side surfaces of the channel pattern NS. The source/drain patterns 150 may be disposed on both sides of the gate structure GS. Subsequently, the capping layer 145 may be formed on the gate structure GS.

As shown in FIG. 18 and FIG. 19, a first open portion OP1 is formed by performing an etching process for removing portions of the interlayer insulation layer 190 and the etch stop layer 185. The etching process is performed to remove portions of the interlayer insulation layer 190 and the etch stop layer 185. The etching process may be performed by, for example, dry etching or wet etching, but is not limited thereto.

At this time, an etching process may be performed after forming a mask pattern (not shown) on the interlayer insulation layer 190. A portion of the interlayer insulation layer 190 not covered by the mask pattern may be removed, and a portion of the interlayer insulation layer 190 covered by the mask pattern may remain. As the interlayer insulation layer 190 is etched, at least a portion of the etch stop layer 185 may be exposed. The etch stop layer 185 exposed by the etching process may also be removed. The etching process may be performed until the upper surface of the third source/drain pattern 153 is exposed.

As a portion of the interlayer insulation layer 190 is removed, the first open portion OP1 extending in the third direction D3 may be formed. The first open portion OP1 may pass through the interlayer insulation layer 190 and the etch stop layer 185 and extend to an upper surface of the third source/drain pattern 153. As the first open portion OP1 is formed, the source/drain pattern 150 may be exposed. For example, at least a portion of the third source/drain pattern 153 may be exposed by the first open portion OP1. In addition, at least a portion of the etch stop layer 185 may be exposed by the first open portion OP1.

At this time, a first end of the contact electrode CT may have a shape in which a width decreases toward the substrate 100 due to a high aspect ratio. For example, a width of the contact electrode CT overlapping the interlayer insulation layer 190 in the first direction D1 may be larger than a width of the contact electrode CT overlapping the second source/drain pattern 152 in the first direction D1, but is not limited thereto.

As shown in FIG. 20 and FIG. 21, a second open portion OP2 is formed by performing an etching process for removing a portion of the source/drain pattern 150.

First, an etching process is performed to remove the third source/drain pattern 153 and the second source/drain pattern 152. The etching process may be performed by, for example, a wet etching method, but is not limited thereto. Etching portions of the third source/drain pattern 153 and the second source/drain pattern 152 may be performed using an etchant having a relatively high etching selectivity for the interlayer insulation layer 190.

Accordingly, the second open portion OP2 may be formed. As the second open portion OP2 is formed by removing a portion of the source/drain pattern 150, the second source/drain pattern 152 may be exposed. In addition, as the second open portion OP2 is formed, a side surface of the third source/drain pattern 153 may be exposed.

As shown in FIG. 22 and FIG. 23, an expansion hole EH is formed by removing the exposed third source/drain pattern 153.

Forming the expansion hole EH may include performing an etching process on the third source/drain pattern 153 exposed by the first open portion OP1. The etching process may be performed using a wet etchant capable of selectively etching the third source/drain pattern 153 among the third source/drain pattern 153 and the second source/drain pattern 152. In addition, the wet etchant may be a wet etchant having a high etching selectivity for the third source/drain pattern 153 among the etch stop layer 185, the interlayer insulation layer 190, and the third source/drain pattern 153.

However, example embodiments are not limited thereto, and dry etching may be used for removing the third source/drain pattern 153 of a semiconductor device according to some embodiments. For example, the third source/drain pattern 153 among the third source/drain pattern 153 and the second source/drain pattern 152 may be selectively etched using the dry etching process.

As the etching process proceeds, the third source/drain pattern 153 may be completely removed. The upper surface of the second source/drain pattern 152 and a lower surface of the etch stop layer 185 may be exposed by the expansion hole EH, a space may be generated between the second source/drain pattern 152 and the etch stop layer 185. In addition, at least a portion of the first source/drain pattern 151 may be exposed by the expansion hole EH. However, but is not limited thereto, a portion of the third source/drain pattern 153 may be removed, and a remaining portion may remain. In this case, a portion of the upper surface of the second source/drain pattern 152 and a portion of the lower surface of the etch stop layer 185 may be exposed by the expansion hole EH. At this time, the first source/drain pattern 151 may not be exposed.

As shown in FIG. 24 and FIG. 25, the contact interface layer 230 is formed in the expansion hole EH.

In more detail, a conductive material may be deposited in a space between the second source/drain pattern 152 and the etch stop layer 185 generated by the expansion hole EH. In other words, a conductive material may be filled in the expansion hole EH. The contact interface layer 230 is conformally formed along an inner wall of the expansion hole EH. The expansion hole EH may be filled without an air gap by the contact interface layer 230. However, example embodiments are not limited thereto, and an air gap may exist in the contact interface layer 230 during deposition of the contact interface layer 230.

The contact interface layer 230 may include the second region 232 positioned between the etch stop layer 185 and the second source/drain pattern 152 and the first region 231 positioned on the second source/drain pattern 152. At this time, the first region 231 may be exposed by the second open portion OP2.

The first region 231 and the second region 232 of the contact interface layer 230 may include same material. In this case, the first region 231 and the second region 232 of the contact interface layer 230 may be integrally formed to be in contact with each other without an interface.

However, example embodiments are not limited thereto, and the first region 231 and the second region 232 of the contact interface layer 230 may include different materials. For example, when the first region 231 includes at least one of titanium (Ti) and titanium nitride (TiN), the second region 232 may include at least one of titanium-silicide, tantalum-silicide, tungsten-silicide, nickel-silicide, and cobalt-silicide.

Accordingly, the contact interface layer 230 may be connected to the second source/drain pattern 152 deposited within the expansion hole EH. In this case, a contact area between the contact interface layer 230 and the second source/drain pattern 152 may be increased compared to a case where the expansion hole EH is not formed. That is, the contact interface layer 230 and the second source/drain pattern 152 may be stably connected.

As shown in FIG. 26 and FIG. 27, the contact electrode CT is formed in the second open portion OP2.

First, the barrier pattern 220 is formed in the second open portion OP2. The barrier pattern 220 deposited on the second open portion OP2 may be conformally formed along the inner wall of the second open portion OP2.

Subsequently, as the planarization process is perform after filling the conductive material, the conductive pattern 210 may be formed. In the process step, a portion of the barrier pattern 220 stacked on the upper surface of the interlayer insulation layer 190 may be removed together. As the contact electrode CT is formed in the second open portion OP2, the width of the second open portion OP2 and the width of the contact electrode CT may correspond to each other. That is, the width of the contact electrode CT may be determined according to the width of the second open portion OP2 formed by removing the interlayer insulation layer 190.

As the contact electrode CT is formed in the second open portion OP2, the contact electrode CT may be in contact with the contact interface layer 230. Specifically, at least a portion of the contact electrode CT may be surrounded by the second region 232 of the contact interface layer 230.

As shown in FIG. 28 and FIG. 29, a semiconductor device according to an embodiment may be formed by forming the upper wiring structure 300 on the contact electrode CT, capping layer, the interlayer insulation layer 190, and the etch stop layer 185.

At this time, at least a portion of the upper wiring structure 300 and the contact electrode CT may be electrically connected. Accordingly, the upper wiring structure 300 may be electrically connected to the source/drain pattern 150 through the contact electrode CT and the contact interface layer 230.

While some embodiments of the present disclosure have been described, it is to be understood that inventive concepts are not limited to the disclosed embodiments, but, on the contrary, are intended to cover various modifications and equivalent arrangements included within the spirit and scope of the appended claims.

What is claimed is:

1. A semiconductor device, comprising:
a substrate;
a lower pattern on the substrate;
a channel pattern on the lower pattern;
a source/drain pattern on both sides of the channel pattern;
a gate structure surrounding the channel pattern;
a contact electrode electrically connected to the source/drain pattern;
an etch stop layer between the gate structure and the contact electrode; and
a contact interface layer on the source/drain pattern, wherein
the contact interface layer includes a first region and a second region,
the first region is between the source/drain pattern and the contact electrode, and
the second region is between the source/drain pattern and the etch stop layer.

2. The semiconductor device of claim 1, wherein the second region of the contact interface layer extends along an upper surface of the source/drain pattern.

3. The semiconductor device of claim 1, wherein the second region overlaps the etch stop layer in a thickness direction of the substrate.

4. The semiconductor device of claim 3, further comprising:
an interlayer insulation layer between the contact electrode and the etch stop layer, wherein
the second region of the contact interface layer overlaps the interlayer insulation layer in the thickness direction of the substrate.

5. The semiconductor device of claim 1, wherein a thickness of the second region of the contact interface layer is greater than a thickness of the first region of the contact interface layer.

6. The semiconductor device of claim 1, wherein
the source/drain pattern comprises a first source/drain pattern on the lower pattern, a second source/drain pattern on the first source/drain pattern, and a third source/drain pattern on an upper surface of the second source/drain pattern; and
the third source/drain pattern is between the second region of the contact interface layer and the first source/drain pattern.

7. The semiconductor device of claim 6, wherein the third source/drain pattern is in contact with the first source/drain pattern.

8. The semiconductor device of claim 6, wherein
an air gap is by a side surface of the second source/drain pattern,
the air gap is defined by a part of the side surface of the second source/drain pattern spaced apart from a part of the etch stop layer and by a part of the third source/drain pattern spaced apart from a part of the second region of the contact interface layer, and
the air gap is between the part of the third source/drain pattern and the part of the second region of the contact interface layer.

9. The semiconductor device of claim 1, wherein an upper surface of the source/drain pattern is farther from an upper surface of the substrate than an upper surface of the channel pattern.

10. A semiconductor device, comprising:
a substrate;
a lower pattern on the substrate;
a channel pattern on the lower pattern;
a source/drain pattern on both sides of the channel pattern;
a gate structure surrounding the channel pattern;
a contact electrode electrically connected to the source/drain pattern; and
a contact interface layer between the source/drain pattern and the contact electrode,
wherein the contact interface layer includes a first region and a second region,
the first region surrounds at least a portion of the contact electrode, and
the second region extends from the first region along an upper surface of the source/drain pattern.

11. The semiconductor device of claim 10, further comprising:
an etch stop layer on both sides of the source/drain pattern, wherein
the second region of the contact interface layer is between the etch stop layer and the source/drain pattern.

12. The semiconductor device of claim 11, wherein the second region of the contact interface layer overlaps the etch stop layer in a thickness direction of the substrate.

13. The semiconductor device of claim 11, further comprising:
an interlayer insulation layer on both sides of the etch stop layer, wherein
the second region of the contact interface layer is between the source/drain pattern and the interlayer insulation layer.

14. The semiconductor device of claim 13, wherein the second region of the contact interface layer overlaps the interlayer insulation layer in a thickness direction of the substrate.

15. The semiconductor device of claim 10, wherein:
the source/drain pattern comprises a first source/drain pattern, a second source/drain pattern, and a third source/drain pattern,
the first source/drain pattern is on the lower pattern,
the second source/drain pattern is on the first source/drain pattern,
the third source/drain pattern is on an upper surface of the second source/drain pattern, and
the third source/drain pattern is between the second region of the contact interface layer and the first source/drain pattern.

16. The semiconductor device of claim 10, wherein the second region of the contact interface layer has a convex shape toward a direction away from the substrate.

17. A semiconductor device, comprising:
a substrate;
a lower pattern on the substrate;
a channel pattern on the lower pattern;
a source/drain pattern on both sides of the channel pattern;
a gate structure surrounding the channel pattern;
a contact electrode electrically connected to the source/drain pattern;
an interlayer insulation layer between the gate structure and the contact electrode; and
a contact interface layer on the source/drain pattern, wherein
the contact interface layer includes a first region and a second region,
the first region is between the source/drain pattern and the contact electrode,
the second region is between the source/drain pattern and the interlayer insulation layer, and
the second region of the contact interface layer overlaps the interlayer insulation layer in a thickness direction of the substrate.

18. The semiconductor device of claim 17, wherein
an internal surface of the second region of the contact interface layer is in contact with the source/drain pattern,
an external surface of the second region of the contact interface layer is in contact with the interlayer insulation layer; and
the internal surface of the second region of the contact interface layer and the external surface of the second region of the contact interface layer each have a convex shape toward a direction away from the substrate.

19. The semiconductor device of claim 17, wherein
an upper surface of the source/drain pattern is farther from an upper surface of the substrate than an upper surface of the channel pattern.

20. The semiconductor device of claim 17, wherein
the source/drain pattern comprises a first source/drain pattern on the lower pattern and a second source/drain pattern on the first source/drain pattern,
an air gap is by a side surface of the second source/drain pattern,
the air gap is defined by a part of the side surface of the second source/drain pattern spaced apart from a part of the interlayer insulation layer and by a part of the source/drain pattern spaced apart from the second region of the contact interface layer, and
the air gap is between the source/drain pattern and the second region of the contact interface layer.
